(19) United States
(12) Patent Application Publication
(10) Pub. No.: US 2024/0404576 A1
(43) Pub. Date: Dec. 5, 2024

(54) Control Circuitry for Scheduling Aspects of Usage-Based Disturbance Mitigation Based on Different External Commands

(71) Applicant: Micron Technology, Inc., Boise, ID (US)

(72) Inventors: Yang Lu, Boise, ID (US); Kang-Yong Kim, Boise, ID (US); Mark Kalei Hadrick, Boise, ID (US)

(73) Assignee: Micron Technology, Inc., Boise, ID (US)

(21) Appl. No.: 18/642,144

(22) Filed: Apr. 22, 2024

Related U.S. Application Data
(60) Provisional application No. 63/504,961, filed on May 30, 2023.

(51) Int. Cl. G11C 11/406; G11C 11/4076; G11C 11/4096

(52) U.S. Cl. CPC G11C 11/40622; G11C 11/4076; G11C 11/4096

(57) ABSTRACT

Apparatuses and methods for scheduling aspects of usage-based disturbance mitigation based on different external commands are described. An apparatus comprises a memory device, which has at least one bank comprising memory cells. A subset of the memory cells is configured to store data associated with usage-based disturbance. The apparatus includes circuitry configured to mitigate usage-based disturbance within the bank. The memory device is configured to receive, from a memory controller, two commands that are separated in time by a timing offset. The memory device is configured to generate an internal read command based on the first command to cause the memory device to read the data from the subset of the memory cells. The memory device is configured to generate an internal write command based on the second command to cause the memory device to write modified data generated by the circuitry to the subset of the memory cells.

### CROSS-REFERENCE TO RELATED APPLICATION(S)

This application claims the benefit of U.S. Provisional Patent Application Ser. No. 63/504,961 filed on May 30, 2023, the disclosure of which is incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of, and techniques for, scheduling aspects of usage-based disturbance mitigation based on different external commands are described with reference to the following drawings. The same numbers are used throughout the drawings to reference like features and components:

FIG. 1 illustrates an example operating environment that can implement control circuitry that schedules aspects of usage-based disturbance mitigation;

FIG. 2 illustrates an example computing system that can implement the control circuitry that schedules aspects of usage-based disturbance mitigation;

FIG. 3 illustrates an example memory device that can schedule aspects of usage-based disturbance mitigation;

FIG. 4 illustrates an example memory array that is partitioned into subsets that store different types of data;

FIG. 5 illustrates example external commands and internal commands for scheduling aspects of usage-based disturbance mitigation;

FIG. 6 illustrates an example sequence of memory operations in which aspects of usage-based disturbance mitigation are implemented;

FIG. 7 illustrates another example sequence of memory operations in which aspects of usage-based disturbance mitigation are implemented; and

FIGS. 8, 9, and 10 illustrate example methods for scheduling aspects of usage-based disturbance mitigation based on different external commands.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification. However, in some implementations, more-reliable memories can sacrifice bit densities, power efficiency, and simplicity.

To meet demands for physically smaller memories, memory devices can be designed with higher chip densities. Increasing chip density, however, can increase electromagnetic coupling (e.g., capacitive coupling) between adjacent or proximate rows of memory cells due, at least in part, to a shrinking distance between these rows. With this undesired coupling, activation (or charging) of a first row of memory cells can sometimes negatively impact a second nearby row of memory cells. In particular, activation of the first row can generate interference, or crosstalk, that causes the second row to experience a voltage fluctuation. In some instances, this voltage fluctuation can cause a state (or value) of a memory cell in the second row to be incorrectly determined by a sense amplifier. Consider an example in which a state of a memory cell in the second row is a “1”. In this example, the voltage fluctuation can cause a sense amplifier to incorrectly determine the state of the memory cell to be a “0” instead of a “1”. Left unchecked, this interference can lead to memory errors or data loss within the memory device.

In some circumstances, a particular row of memory cells is activated repeatedly in an unintentional or intentional (sometimes malicious) manner. Consider, for instance, that memory cells in an R^{th} row are subjected to repeated activation, which causes one or more memory cells in an adjacent row (e.g., within an R+1 row, an R+2 row, an R−1 row, and/or an R−2 row) to change states. This effect is referred to as usage-based disturbance. The occurrence of usage-based disturbance can lead to corruption or changing of contents within the affected row of memory.

Some memory devices include usage-based disturbance circuitry, which monitors and mitigates usage-based disturbance within rows of a memory device. The usage-based disturbance circuitry can include at least one counter circuit for detecting a condition associated with usage-based disturbance. A subset of memory cells in one or more rows of the memory device can store an activation count, which is referenced by the counter circuit. With the activation count, the usage-based disturbance circuitry can monitor (e.g., track) how many times and/or how often one or more rows of a memory device are activated. When a row of a memory device is activated, the memory device reads data from the row and the counter circuit increments the activation count. In some instances, the usage-based disturbance circuitry can selectively cause one or more rows within the memory device to be refreshed based on an activation count of a row exceeding a threshold. The usage-based disturbance circuitry can also detect and/or correct bit errors, which may have been caused by usage-based disturbance.

According to some protocols, the memory controller sequentially transmits to the memory device a precharge command before transmitting an activate command associated with a normal read/write operation. The precharge command and the activate command are separated by a timing offset. The precharge command causes the memory device to de-activate or close a row that is currently open, thus allowing a new row to be prepared for read/write operations. After transmitting the precharge command, the memory controller waits for a precharge time and thereafter transmits the activate command associated with the next operation. The activate command is essentially a row access command that causes the memory device to open a new row. The precharge time represents a timing offset or a latency between the transmission of the precharge command and the transmission of the activate command. The precharge time is necessary to allow the memory device to complete de-activation of an open row so that a new row can be opened. Because the activate command causes the memory device to open a new row, the memory device executes read/write operations in the currently opened row during the precharge time prior to receiving the activate command.

In some existing usage-based disturbance mitigation techniques, in response to the precharge command, the usage-based disturbance mitigation circuitry sequentially executes an internal read operation and an internal write operation. The internal read operation and the internal write operation are different than normal read/write operations. During the internal read operation, the usage-based disturbance circuitry reads data from the row. During the internal write operation, the usage-based disturbance circuitry increments an activation count stored within the activated row. Because the activate command causes the memory device to open a new row, the time available to perform usage-based disturbance mitigation is limited to the precharge time. According to existing methods, to allow the memory device to complete the internal read and internal write operations within the precharge time, the internal read and write operations are executed back-to-back without any timing offset between the two operations. For example, in response to the precharge command, the usage-based disturbance mitigation circuitry generates the internal read command, completes the internal read operation, and immediately thereafter generates the internal write command and completes the internal write operation.

A drawback of existing methods is that because the internal read and internal write operations are executed back-to-back, there is limited time to allow for additional operations to mitigate usage-based disturbance prior to the execution of the internal write operation. The internal read operation, for example, may require 5 nanoseconds (ns), which can be insufficient time to correct errors caused by the usage-based disturbance.

A further drawback of existing methods is that the precharge operation is delayed relative to the precharge command so that the internal read and internal write operations can be executed. The effect of this delay is that an external precharge time, which represents a timing offset between the precharge command and the activate command, is increased, thus degrading the overall performance of the memory device.

To address this and other issues regarding usage-based disturbance, this document describes control circuitry that supports usage-based disturbance mitigation in a memory device. In contrast to existing usage-based disturbance mitigation techniques that typically generate both the internal read and the internal write command based on a same command, the control circuitry described in this document generates the internal read command based on a first command and generates the internal write command based on a second command. The first and second commands are external commands received from a memory controller. In some example implementations, the first command is an activate command and/or the second command is a precharge command. In some example implementations, the internal read operation, which is performed in response to the internal read command, and the internal write operation, which is performed in response to the internal write command, are not executed back-to-back. As such, there is a timing offset between the two operations that allows error corrections and other tasks associated with usage-based disturbance mitigation to be performed prior to the internal write operation. Also, because the internal read operation is not executed during the external precharge time, the external precharge time can be reduced compared to existing methods, thus improving the overall performance of the memory device. Furthermore, because the internal read operation is not executed during the external precharge time, additional time can be allocated for the execution of the internal write operation during the external precharge time.

### Example Operating Environments

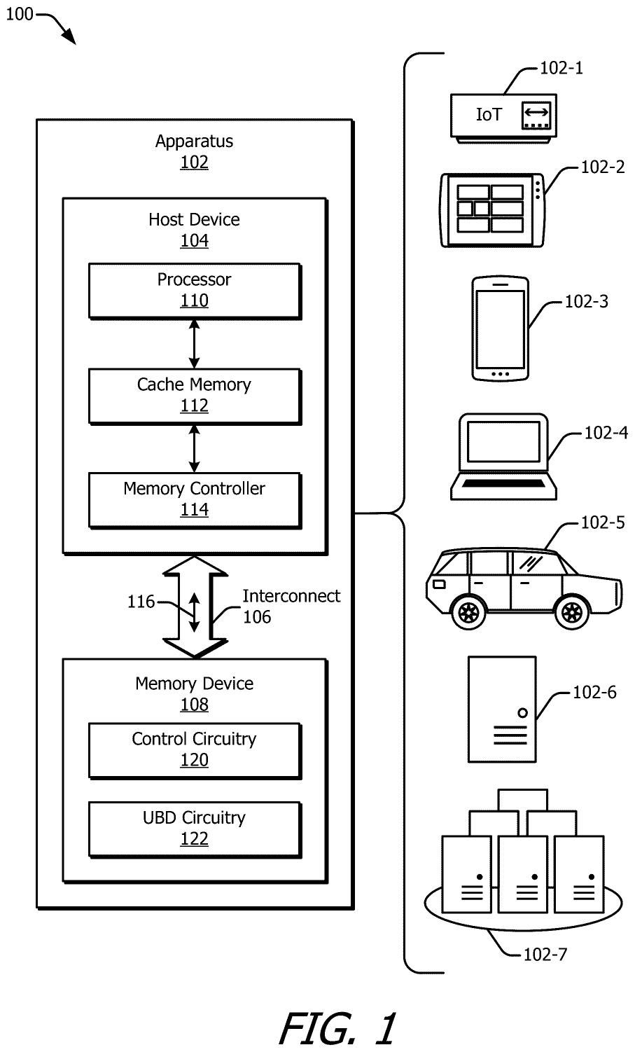

FIG. 1 illustrates, at 100 generally, an example operating environment including an apparatus 102 that can implement control circuitry that schedules aspects of usage-based disturbance mitigation. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, or sensor, or electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes control circuitry 120 and usage-based disturbance circuitry 122 (UBD circuitry 122). The control circuitry 120 can include various components that the memory device 108 can use to perform various operations, such as communicating with other devices, managing memory performance, performing refresh operations (e.g., self-refresh operations or auto-refresh operations), and supporting usage-based disturbance mitigation.

To support usage-based disturbance mitigation, the control circuitry 120 generates internal commands based on external commands received from the memory controller 114. In some example implementations, the control circuitry 120 generates an internal read command based on an external command (also referred to as a first command) and generates an internal write command based on another external command (also referred to as a second command). Thus, the internal read command and the internal write command are generated in response to different external commands. In some example implementations, the first command is an activate command and/or the second command is a precharge command. These internal commands are executed to support usage-based disturbance mitigation in the memory device 108. The different external commands can be scheduled sequentially or can be further separated by another external command, such as a read or write command. By scheduling the internal read and write commands across multiple external commands, the usage-based disturbance circuitry can perform aspects of usage-based disturbance mitigation over an extended period of time compared to a shorter amount of time available if these commands were scheduled based on a same external command.

The usage-based disturbance circuitry 122 is configured to monitor and mitigate usage-based disturbance in the memory device 108. In some example implementations, the usage-based disturbance circuitry 122 includes at least one counter circuit for detecting a condition associated with usage-based disturbance, at least one queue for mitigating usage-based disturbance, and at least one error-correction-code (ECC) circuit for detecting and/or correcting bit errors. The usage-based disturbance circuitry 122 can be implemented using software, firmware, hardware, fixed logic circuitry, or combinations thereof.

In some example implementations, the usage-based disturbance circuitry 122 may include logic to increment an activation count associated with a row of memory cells that is activated. The usage-based disturbance circuitry 122 may include a dedicated counter circuit (not illustrated in FIG. 1) whose activation count is incremented when an associated row of memory cells is activated. The usage-based disturbance circuitry 122 can monitor (e.g., track) how many times and/or how often one or more rows of a memory device are activated. When a row of a memory device is activated, the usage-based disturbance circuitry 122 reads data (e.g., the activation count) from the row and causes the memory device 108 to increment the counter circuit. The counter circuit stores an activation count that represents how many times the row has been activated. In some instances, the usage-based disturbance circuitry 122 can selectively cause one or more rows within the memory device to be refreshed based on an activation count of a row exceeding a threshold.

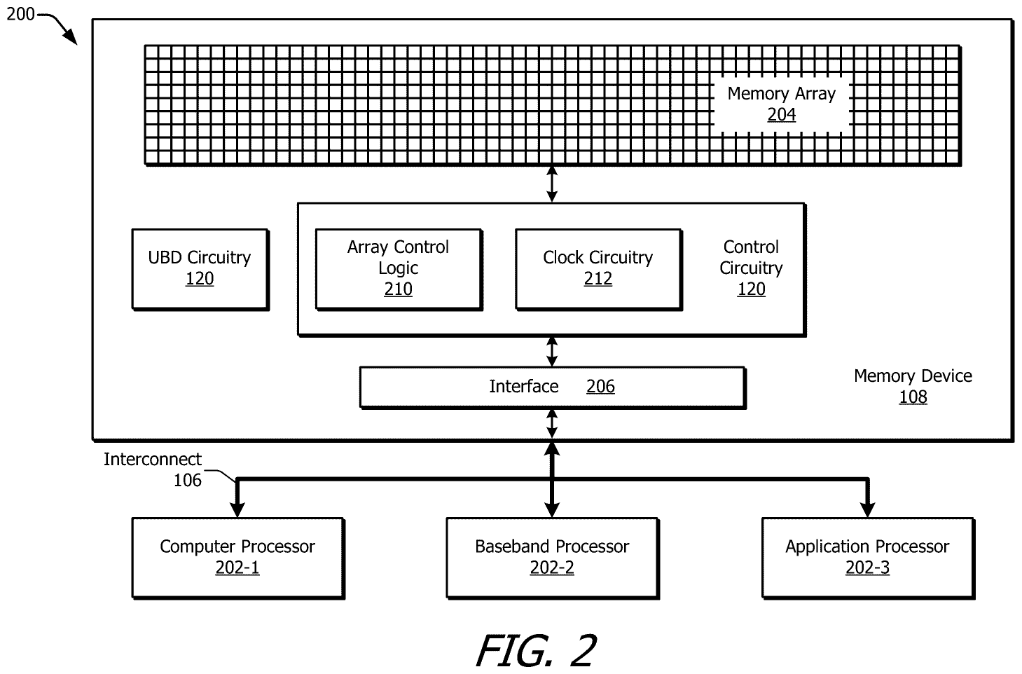

FIG. 2 illustrates an example computing system 200 that can implement aspects of the control circuitry 120 that supports usage-based disturbance mitigation. In some implementations, the computing system 200 includes at least one memory device 108, at least one interconnect 106, and at least one processor 202. The memory device 108 can include, or be associated with, at least one memory array 204, at least one interface 206, and the control circuitry 120 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 120 may be components on a single semiconductor die or on separate semiconductor dies. The memory array 204 or the control circuitry 120 may also be distributed across multiple dies.

The array control logic 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality.

In some aspects, the usage-based disturbance circuitry 122 can be considered part of the control circuitry 120. For example, the usage-based disturbance circuitry 122 can be part of the array control logic 210. As another example, the usage-based disturbance circuitry 122 can be another circuit of the control circuitry 120.

The interface 206 can couple the control circuitry 120 or the memory array 204 directly or indirectly to the interconnect 106. In some implementations, the usage-based disturbance circuitry 122, the array control logic 210, and the clock circuitry 212 can be part of a single component (e.g., the control circuitry 120). In other implementations, one or more of the usage-based disturbance circuitry 122, the array control logic 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within a same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and be referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices).

### Example Techniques and Hardware

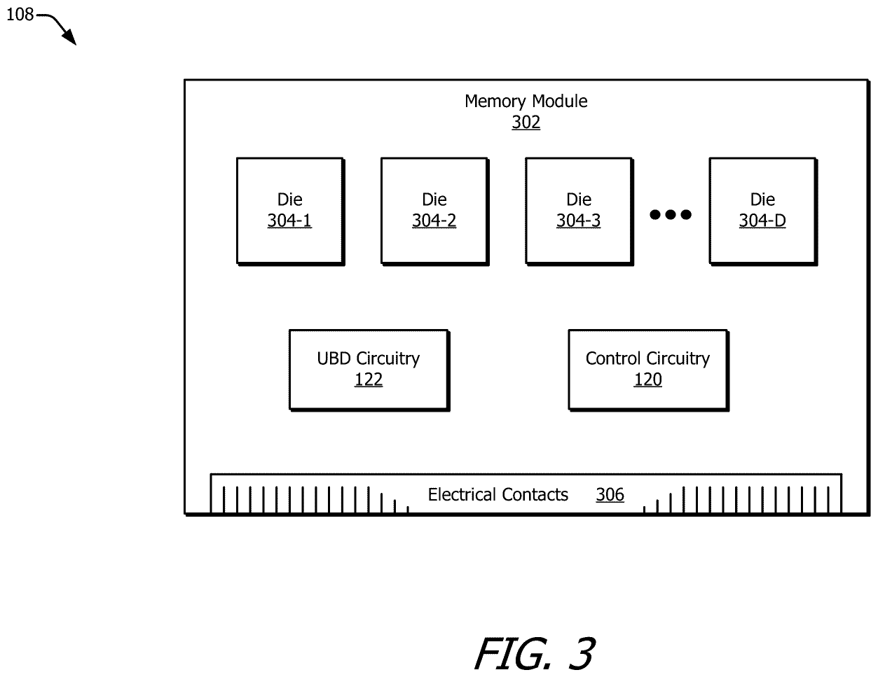

FIG. 3 illustrates an example memory device 108 that can schedule aspects of usage-based disturbance mitigation based on different external commands. The memory device 108 includes a memory module 302, which can include multiple dies 304. As illustrated, the memory module 302 includes a first die 304-1, a second die 304-2, a third die 304-3, and a Dth die 304-D, with D representing a positive integer. The memory module 302 can be a SIMM or a DIMM. As another example, the memory module 302 can interface with other components via a bus interconnect (e.g., a Peripheral Component Interconnect Express (PCIe®) bus). The memory device 108 illustrated in FIGS. 1 and 2 can correspond, for example, to multiple dies (or dice) 304-1 through 304-D, or a memory module 302 with two or more dies 304. As shown, the memory module 302 can include one or more electrical contacts 306 (e.g., pins) to interface the memory module 302 to other components.

In some example embodiments, the control circuitry 120 and/or the usage-based disturbance circuitry 122 can manage usage-based disturbance mitigation across multiple dies 304. In other example embodiments, the memory module 302 can include multiple instances of the control circuitry 120, with each one configured to support aspects of usage-based disturbance in a particular die 304. In yet other example embodiments, the usage-based disturbance circuitry 122 can be implemented within each die 304, with each one configured to monitor and mitigate usage-based disturbance in a particular die 304.

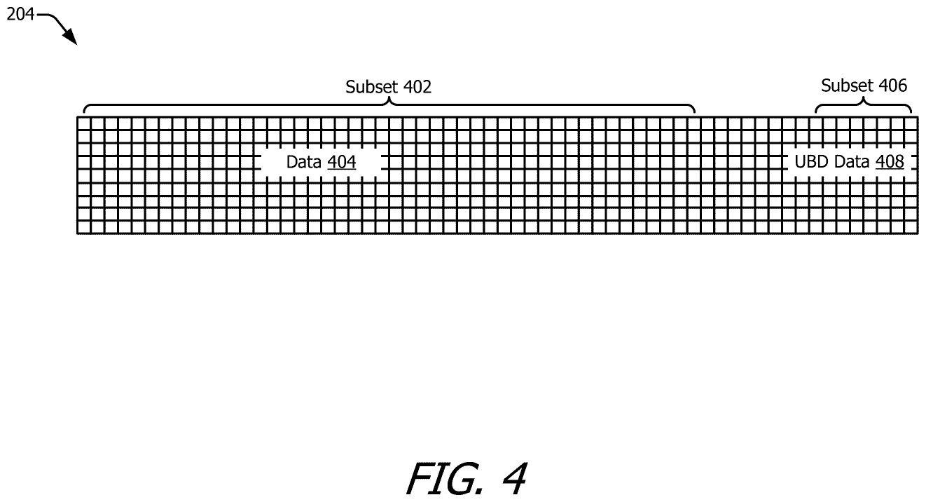

The memory module 302 can be implemented in various manners. For example, the memory module 302 may include a printed circuit board, and the multiple dies 304-1 through 304-D may be mounted or otherwise attached to the printed circuit board. The dies 304 (e.g., memory dies) may be arranged in a line or along two or more dimensions (e.g., forming a grid or array). The dies 304 may have a similar size or may have different sizes. Each die 304 may be similar to another die 304 or different in size, shape, data capacity, or control circuitries. The dies 304 may also be positioned on a single side or on multiple sides of the memory module 302. Each die 304 can include a memory array 204, which can store data associated with usage-based disturbance mitigation, as further described with respect to FIG. 4.

FIG. 4 illustrates the memory array 204, which is partitioned into subsets that store different types of data. A subset 402 of memory cells of the memory array 204 stores data 404, which can be associated with a read or write operation. Another subset 406 of the memory cells of the memory array 204 stores usage-based disturbance data 408 (UBD data 408), which can be associated with the internal read and write operations. The internal read and write operations are executed to support aspects of usage-based disturbance mitigation. The usage-based disturbance mitigation can include reading the usage-based disturbance data 408 from the subset 406 of memory cells and/or writing the usage-based disturbance data 408 (e.g., usage-based disturbance data 408 that has been modified or updated) to the subset 406 of memory cells.

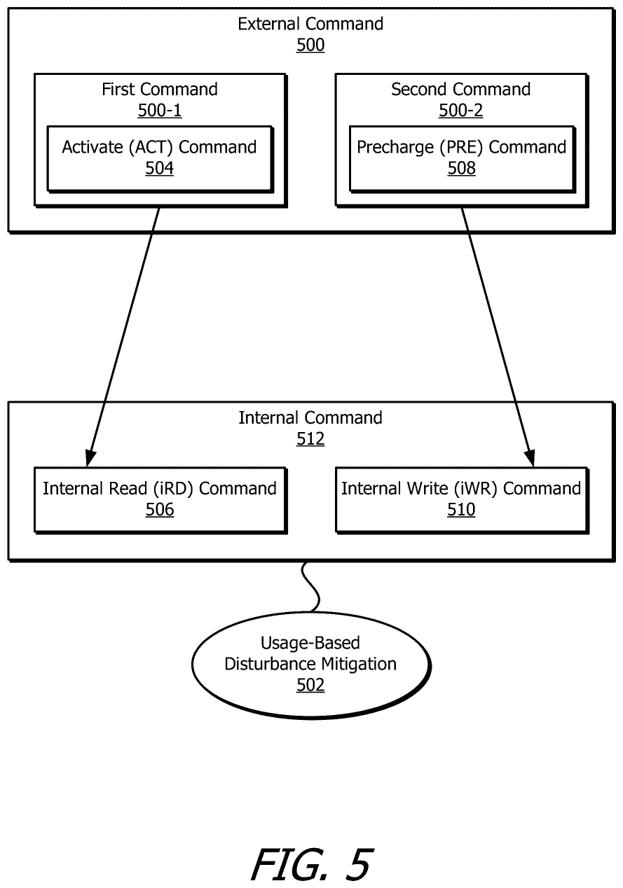

In an example implementation, the usage-based disturbance data 408 includes bits that represent a quantity of activations (e.g., an activation count or active count) since a last refresh for one or more rows of the memory cells. The usage-based disturbance data 408 can also include parity bits. Although in FIG. 4 the subset 406 of the memory array 204 is illustrated as comprising far-right columns of memory cells closest to a right boundary of the memory array 204, the subset 406 can comprise far-left columns of memory cells closest to a left boundary of the memory array 204, or the subset 406 can comprise columns of memory cells along the middle of the memory array 204. In some example embodiments, each row of the memory array 204 includes memory cells that store the usage-based disturbance data 408 associated with the row. The reading and writing of the usage based disturbance data 408 can be performed based on different external commands, as further described with respect to FIG. 5.

FIG. 5 illustrates example external commands 500 and internal commands 512 for scheduling aspects of usage-based disturbance mitigation 502. In particular, the memory device 108 generates the internal commands 512 based on the external commands 500. The usage-based disturbance mitigation 502 can include reading usage-based disturbance data 408 from the subset 406 of memory cells of the memory array 204 and/or writing usage-based disturbance data 408 to the subset 406 of memory cells of the memory array 204.

Example external commands 500 that cause the memory device 108 to schedule aspects of usage-based disturbance mitigation 502 include a first command 500-1 and a second command 500-2. In some example embodiments, the first command 500-1 is an activate command 504 (ACT 504), and the second external command 500-2 is a precharge command 508 (PRE 508). The activate (ACT) command 504 and the precharge (PRE) command 508 are transmitted by the memory controller 114 and received by the memory device 108. In response to the activate command 504, the memory device 108 generates an internal read command 506 (iRD 506), and in response to the precharge command 508, the memory device 108 generates an internal write command 510 (iWR 510).

In some implementations, the memory device 108 can perform a first portion of usage-based disturbance mitigation 502 in response to the activate command 504 and can perform a second portion of usage-based disturbance mitigation 502 in response to the precharge command 508. The first portion of usage-based disturbance mitigation 502 may include generating the internal read command 506 and executing an internal read operation. The second portion of usage-based disturbance mitigation 502 may include generating the internal write command 510 and executing an internal write operation.

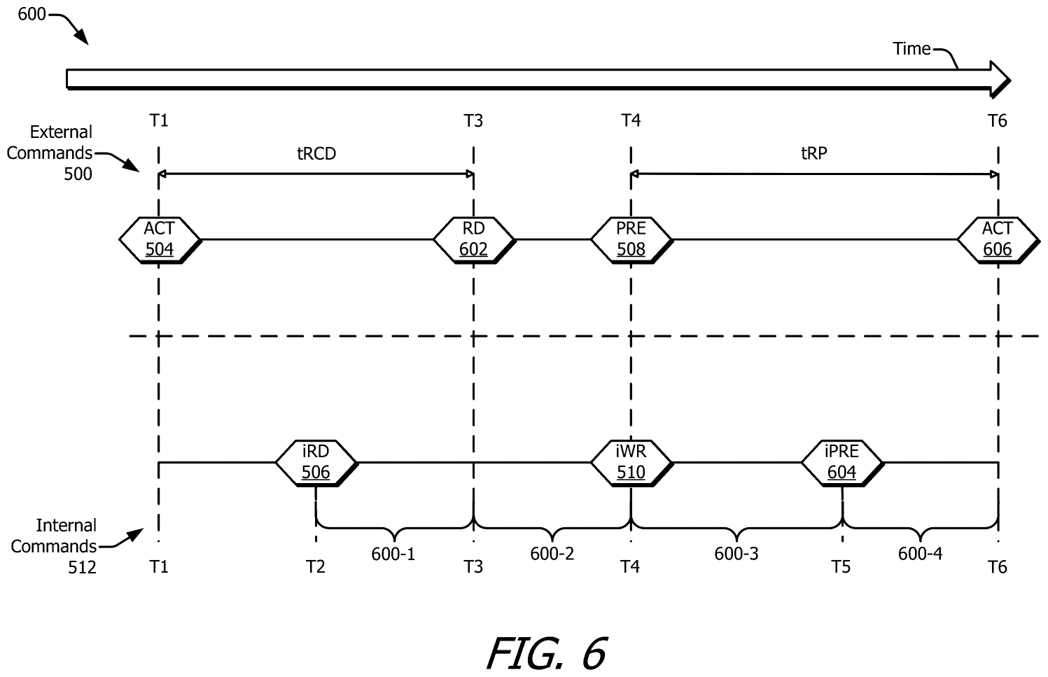

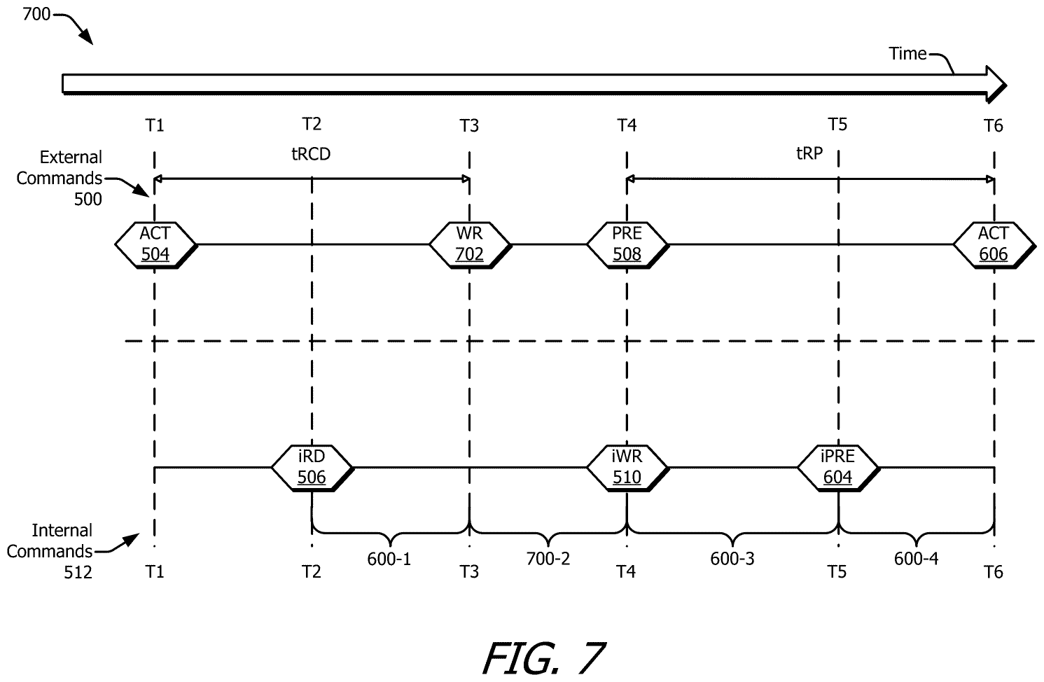

The internal read/write operations are different than normal read/write operations. During the internal read operation, the memory device 108 reads usage-based disturbance data 408 from the subset 406 of memory cells. During the internal write operation, the memory device 108 writes modified usage-based disturbance data 408 to the subset 406 of memory cells. For example, the modified data may include an updated activation count that is used by the memory device 108 to increment a counter that can be stored within the subset 406 of memory cells. In some example embodiments, the usage-based disturbance circuitry 122 may pass the updated activation count to a write driver circuit (not illustrated in FIG. 5), which writes the updated activation count to the subset 406 of memory cells. The external commands 500, the internal commands 512, and various resulting memory operations are further described with respect to FIGS. 6 and 7.

FIG. 6 illustrates an example sequence of memory operations 600 in which aspects of usage-based disturbance mitigation 502 are implemented in response to different external commands 500 from the memory controller 114. More specifically, FIG. 6 illustrates aspects of usage-based disturbance mitigation 502 implemented in response to the activate command 504 and the precharge command 508 from the memory controller 114. Time is shown as elapsing from left to right.

The external commands 500 that are transmitted by the memory controller 114 and received by the memory device 108 are shown towards the top of FIG. 6. The internal commands 512 that are generated and executed by the memory device 108 are shown towards the bottom of FIG. 6. The time between commands is not necessarily drawn to scale in FIG. 6.

At time T1, the memory device 108 receives the activate command 504 (ACT 504) from the memory controller 114. In response, at time T2, the memory device 108 (e.g., the control circuitry 120) generates the internal read command 506 (iRD 506), which causes the memory device 108 to perform an internal read operation 600-1. In a departure from existing usage-based disturbance mitigation techniques in which a conventional memory device generates an internal read command based on a precharge command, in the disclosed embodiments, the internal read command 506 is generated based on the activate command 504.

At time T3, the memory controller 114 issues a read command 602 (RD 602), which is associated with a normal read operation. A timing offset between the activate command 504 and the read command 602 is represented by tRCD. In some example embodiments, the timing offset tRCD is sufficient to allow the memory device 108 to complete the internal read operation 600-1 prior to the read command 602. In other example embodiments, the internal read operation 600-1 may partially overlap the read command 602.

The memory device 108 performs a normal read operation 600-2 in response to the read command 602. At time T4, the memory controller 114 issues the precharge command 508. In response, the memory device 108 generates an internal write command 510 that causes the memory device 108 to perform an internal write operation 600-3. In some example embodiments, the memory device 108 generates the internal write command 510 immediately upon receiving the precharge command 508.

Because the precharge command 508 causes the memory device 108 to de-activate a row that is currently open, the memory controller 114 waits for a sufficient time (e.g., until time T4) to issue the precharge command 508 to allow the memory device 108 to complete the normal read operation 600-2. Furthermore, to allow a sufficient time for the internal write operation 600-3 to be completed before the de-activation of the row that is currently open, the memory device 108 delays execution of the precharge command 508 to enable the internal write operation 600-3 to complete. As such, the memory device 108 issues an internal precharge command 604 (iPRE 604) at time T5. Thus, an actual precharge operation 600-4 does not begin immediately at time T4 in response to the precharge command 508, but is delayed until the time T5. Because a next activate command 606 from the memory controller 114 causes the memory device 108 to open a new row, the memory controller 114 waits until time T6 to issue the next activate command 606 so the precharge operation 600-4 can be completed before the next activate command 606. A timing offset between the precharge command 508 and the next activate command 606 is represented by tRP. The timing offset tRP is sufficient to allow the memory device 108 to execute the internal write operation 600-3 and the precharge operation 600-4, while the timing offset tRCD allows the memory device 108 to execute the internal read operation 600-1 at least partially.

Because the internal read operation 600-1 is executed, at least partially, during the timing offset tRCD but the internal write operation 600-3 is executed during the timing offset tRP, the memory device 108 has less timing restraint to perform the internal read operation 600-1 and the internal write operation 600-3 Furthermore, in this example, the internal read operation 600-1 and internal write operation 600-3 are separated by the normal read operation 600-2 (e.g., are not executed back-to-back or sequentially). As such, the usage-based disturbance circuitry 122 can utilize the time associated with the normal read operation 600-2 to perform other usage-based disturbance mitigation tasks, including error corrections, prior to the internal write operation 600-3. Also, because the internal read operation 600-1 is not executed during the timing offset tRP but instead is executed during the timing offset tRCD, the duration of the tRP can be reduced, thus improving the overall performance of the memory device. Furthermore, additional time can be allocated for the execution of the internal write operation 600-3 within the timing offset tRP. In some example embodiments, the memory device 108 can generate the internal read command 506 based on the read command 602. In such embodiments, the memory device 108 can execute the internal read operation 600-1 prior to receiving the precharge command 508 from the memory controller 114.

In some example embodiments, the memory device 108 can alternatively generate the internal read command 506 based on another external command 500, such as the read command 602. In such embodiments, the memory device 108 can execute the internal read operation 600-1 prior to receiving the precharge command 508 from the memory controller 114.

In other example embodiments, the memory device 108 can generate the internal write command 510 based on another external command 500, such as the read command 602. In such embodiments, the memory device 108 can sequentially execute the internal read operation 600-1, the normal read operation 600-2, and the internal write operation 600-3 prior to receiving the precharge command 508 from the memory controller 114. In general, the internal read command 506 or the internal write command 510 can be generated in response to any external command 500 that allows sufficient time for performing the corresponding operation prior to the memory device performing the precharge operation 600-4.

FIG. 7 illustrates an example sequence of memory operations 700 in which aspects of usage-based disturbance mitigation 502 are implemented in response to different external commands from the memory controller 114. More specifically, FIG. 7 illustrates aspects of usage-based disturbance mitigation 502 implemented in response to the activate command 504, a write command 702, and the precharge command 508 from the memory controller 114. Time is shown as elapsing from left to right.

The external commands 500 that are transmitted by the memory controller 114 and received by the memory device 108 are shown towards the top of FIG. 7. The internal commands 501 that are generated and executed by the memory device 108 are shown towards the bottom of FIG. 7. The time between commands is not necessarily drawn to scale in FIG. 7.

At time T1, the memory controller 114 issues the activate command 504 (ACT 504). In response, at time T2, the memory device 108 (e.g., the control circuitry 120) generates the internal read command 506 (iRD 506), which causes the memory device 108 to perform the internal read operation 600-1. In contrast to existing usage-based disturbance mitigation techniques in which a conventional memory device generates an internal read command based on a precharge command, in the disclosed embodiments, the internal read command 506 is generated based on the activate command 504.

At time T3, the memory controller 114 issues the write command 702 (WR 702), which is associated with a normal write operation. A timing offset between the activate command 504 and the write command 702 is represented by tRCD. The timing offset tRCD is sufficient to allow the memory device 108 to complete the internal read operation 700-1.

The memory device 108 executes a normal write operation 700-2 in response to the write command 702. At time T4, the memory controller 114 issues the precharge command 508. In response, the memory device 108 generates the internal write command 510, which causes the memory device 108 to perform the internal write operation 600-3.

Because the precharge command 508 causes the memory device 108 to de-activate a row that is currently open, the memory controller 114 waits until the time T4 to issue the precharge command 508 to provide sufficient time for the memory device 108 to complete the normal write operation 700-2. Also, to allow the internal write operation 700-3 to be completed before the de-activation of the row that is currently open, the execution of the precharge command 508 is delayed until the internal precharge command 604 (iPRE 604) is issued by the control circuitry 120 at the time T5. Thus, an actual precharge operation 700-4 does not begin immediately following the precharge command 508 but is delayed relative to the time T4 until the time T5. Because the next activate command 606 from the memory controller 114 causes the memory device 108 to open a new row, the memory controller 114 waits until time T6 to allow sufficient time to complete the precharge operation 600-4. The timing offset between the precharge command 508 and the next activate command 606 is represented by tRP. The timing offset tRP is sufficient to complete the internal write operation 600-3 and the precharge operation 600-4.

Because the internal read operation 700-1 is executed during the timing offset tRCD but the internal write operation 700-3 is executed during the timing offset tRP, the internal read operation 700-1 and the internal write operation 700-3 are not executed back-to-back, which results in a delay between the two operations. As such, error corrections and other tasks can be performed prior to the execution of the internal write operation 700-3. Also, because the internal read operation 700-1 is not executed during the timing offset tRP but instead is executed in the timing offset tRCD, the duration of the tRP can be reduced, thus improving the overall performance of the memory device 108.

In some example embodiments, the memory device 108 can generate the internal read command 506 based on another external command 500, such as the write command 702. In such embodiments, the memory device 108 can execute the internal read operation 600-1 prior to receiving the precharge command 508 from the memory controller 114.

In other example embodiments, the memory controller 114 can generate the internal write command 510 based on another external command 500, such as the write command 702. In such embodiments, the memory device 108 can sequentially execute the internal read operation 600-1, the normal write operation 700-2, and the internal write operation 600-3 prior to receiving the precharge command 508 from the memory controller 114. In general, the internal read command 506 or the internal write command 510 can be generated in response to any external command 500 that allows sufficient time for performing the corresponding operation prior to the memory device performing the precharge operation 600-4.

### Example Methods

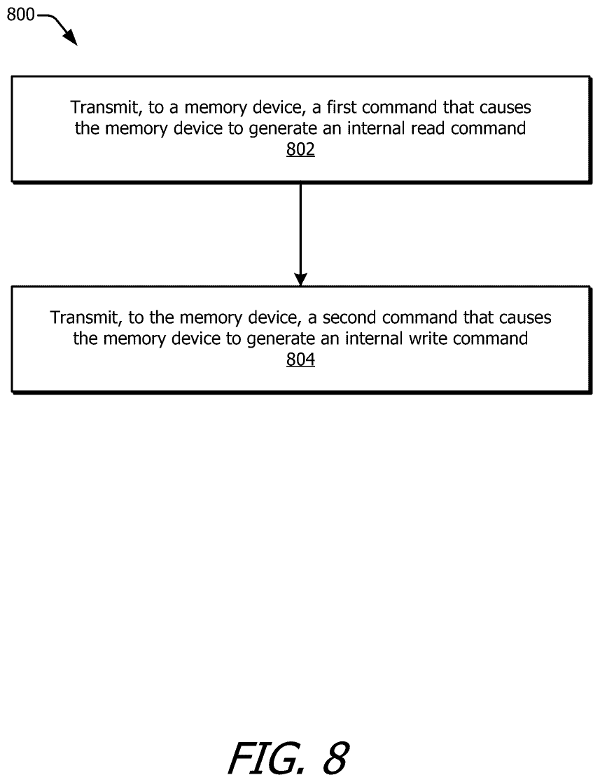

This section describes example methods for scheduling aspects of usage-based disturbance mitigation based on different external commands with reference to diagrams of FIGS. 8, 9, and 10. These descriptions may also refer to components, entities, and other aspects depicted in FIGS. 1 to 7 by way of example only. The described methods are not necessarily limited to performance by one entity or multiple entities operating on one device.

FIG. 8 illustrates a method 800, which includes operations 802 through 804. In aspects, operations of the method 800 are implemented by or with the memory controller 114 described with reference to FIGS. 1 to 7. The operations include transmission by the memory controller 114 of two different external commands to the memory device 108. In response to the first external command 500-1, the memory device 108 generates the internal read command 506, and in response to the second external command 500-2, the memory device 108 generates the internal write command 510.

At 802, the memory controller 114 transmits the first command 500-1 to the memory device 108. The first command 500-1 is an external command 500 received by the memory device 108. The first command 500-1 causes the memory device 108 to generate the internal read command 506, e.g., as shown in FIG. 6.

At 804, the memory controller 114 transmits the second command 500-2 to the memory device 108. The second command 500-2 is an external command 500 received by the memory device 108. The second command 500-2 causes the memory device 108 to generate the internal write command 510. In some example embodiments, the first command 500-1 is an activate command 504 and the second command 500-2 is a precharge command 508.

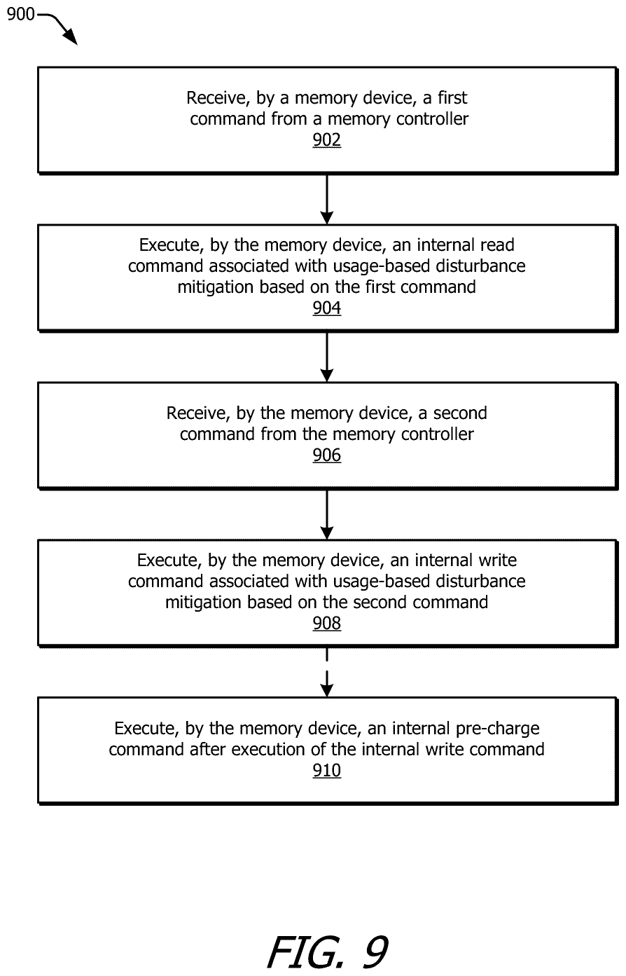

FIG. 9 illustrates a method 900, which includes operations 902 through 910. In aspects, operations of the method 900 are implemented by or with the memory device 108 as described with reference to FIGS. 1 to 7. The operations of the method 900 include receiving by the memory device 108 two different external commands from the memory controller 114. In response to the first external command 500-1, the memory device 108 generates the internal read command 506. In response to the second external command 500-2, the memory device 108 generates the internal write command 510.

At 902, the memory device 108 receives the first command 500-1 from the memory controller 114. The first command 500-1 causes the memory device 108 to generate the internal read command 506. In some example embodiments, the first command 500-1 is an activate command 504. At 904, the memory device 108 executes the internal read command 506 associated with usage-based disturbance mitigation based on the first command 500-1. To execute the internal read command 506, the memory device 108 performs the internal read operation 600-1. The internal read operation 600-1 is completed before the memory device 108 receives the second command 500-2 from the memory controller 114. In some example embodiments, the second command 500-2 is a precharge command 508. The first command 500-1 and the second command 500-2 may or may not be sequential commands. In some implementations, the memory device receives a third command, such as the read or write command, between the first command 500-1 and the second command 500-2.

At 906, the memory device 108 receives the second command 500-2 from the memory controller 114. The second command 500-2 causes the memory device 108 to generate the internal write command 510. The first command 500-1 and the second command 500-2 are separated in time by at least a timing offset that enables the memory device 108 to execute the internal read operation 600-1 prior to the second command 500-2.

At 908, the memory device 108 executes the internal write command 510 associated with usage-based disturbance mitigation based on the second command 500-2. To execute the internal write command 510, the memory device performs the internal write operation 600-3. In some example embodiments, at 910, the memory device 108 can optionally execute the internal precharge operation 600-4 after the execution of the internal write operation 600-3 and prior to receiving a next activate command 606.

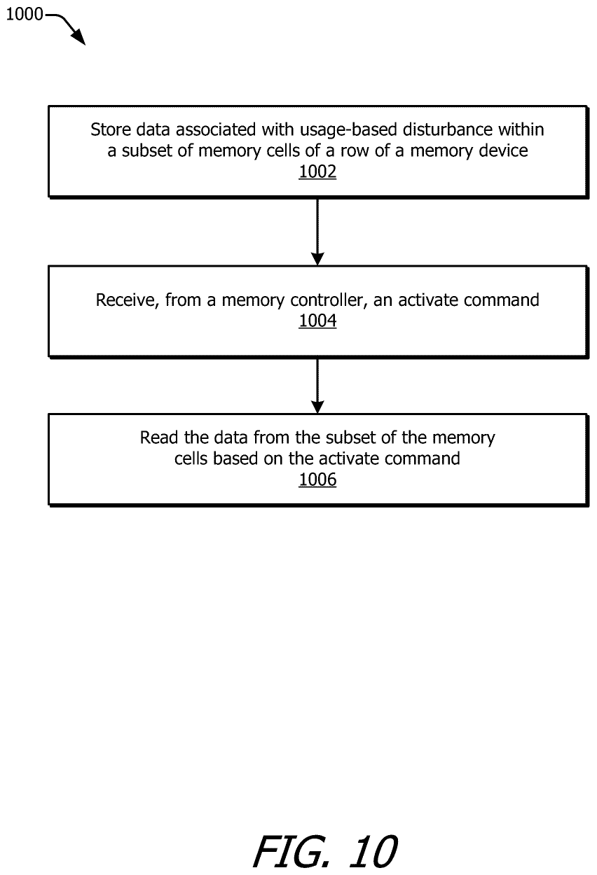

FIG. 10 illustrates a method 1000, which includes operations 1002 through 1006. In aspects, operations of the method 1000 are implemented by or with the memory device 108 as described with reference to FIGS. 1 to 7. The operations include configuring a subset of memory cells of a row of the memory device 108 to store data associated with usage-based disturbance, receiving from the memory controller 114 the first command 500-1, and generating by the memory device 108 the internal read command 506 in response to the first command 500-1.

At 1002, a subset of memory cells of a row of the memory device 108 is configured to store data associated with usage-based disturbance. At 1004, the memory device 108 receives the activate command 504 from the memory controller 114. In this example, the activate command 504 represents the first command 500-1. At 1006, the memory device 108 generates the internal read command 506 based on the activate command 504. The internal read command 506 causes the memory device 108 to read the data from the subset of memory cells.

For the figures described above, the orders in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-logic circuitry or a processor in conjunction with a memory), firmware, software, or some combination thereof. The methods may be realized using one or more of the apparatuses or components shown in FIGS. 1 to 7, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media, including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for scheduling aspects of usage-based disturbance mitigation based on different external commands are described:

Example 1: An apparatus comprising:
a memory device comprising:
   at least one bank comprising memory cells, wherein a subset of the memory cells is configured to store data associated with usage-based disturbance; and
   circuitry configured to mitigate usage-based disturbance within the bank based on the data,
the memory device configured to:
   receive, from a memory controller, two commands that are separated in time by a timing offset;
   generate an internal read command based on a first command of the two commands to cause the memory device to read the data from the subset of the memory cells; and
   generate an internal write command based on a second command of the two commands to cause the memory device to write modified data generated by the circuitry to the subset of the memory cells.

Example 2: The apparatus of example 1 or any other example, wherein the first command received from the memory controller is an activate command.

Example 3: The apparatus of example 1 or any other example, wherein the second command received from the memory controller is a precharge command.

Example 4: The apparatus of example 1 or any other example, wherein the memory device is configured to read the data from the subset of the memory cells based on the internal read command prior to receiving the second command.

Example 5: The apparatus of example 4 or any other example, wherein a timing offset between the first command and the second command at least includes a row address strobe (RAS) delay and a column address strobe (CAS) delay (tRCD).

Example 6: The apparatus of example 1 or any other example, wherein the memory device is configured to write the modified data to the subset of the memory cells prior to receiving a subsequent command.

Example 7: The apparatus of example 6 or any other example, wherein a timing offset between the second command and a subsequent command corresponds to a precharge time (tRP).

Example 8: The apparatus of example 1 or any other example, wherein the subset represents a subset of the memory cells within each row of the bank.

Example 9: An apparatus comprising:
a memory device comprising a plurality of memory cells arranged in rows, a subset of the memory cells configured to store data associated with usage-based disturbance in the rows,
the memory device configured to:
   receive, from a memory controller, an activate command; and
   read the data from the subset of the memory cells based on the activate command.

Example 10: The apparatus of example 9 or any other example, wherein the memory device is configured to:
receive, from the memory controller, a precharge command that is separated in time from the activate command; and
write modified data generated based on the data to the subset of the memory cells based on the precharge command.

Example 11: The apparatus of example 10 or any other example, wherein the memory device is configured to read the data from the subset of the memory cells prior to receiving the precharge command.

Example 12: The apparatus of example 10 or any other example, wherein the memory device is configured to write the modified data to the subset of the memory cells prior to receiving a subsequent command.

Example 13: The apparatus of example 9 or any other example, wherein:
each row includes the subset of the memory cells configured to store the data associated with usage-based disturbance;
the activate command is associated with a particular row; and
the memory device is configured to read the data from the row associated with the activate command.

Example 14: A method comprising:
receiving, by a memory device, a first command from a memory controller;
executing, by the memory device, an internal read command associated with usage-based disturbance mitigation based on the first command;
receiving, by the memory device, a second command from the memory controller; and
executing, by the memory device, an internal write command associated with usage-based disturbance mitigation based on the second command.

Example 15: The method of example 14 or any other example, wherein the receiving of the first command comprises receiving an activate command from the memory controller.

Example 16: The method of example 14 or any other example, wherein the receiving of the second command comprises receiving a precharge command from the memory controller.

Example 17: The method of example 16 or any other example, further comprising:
generating, by the memory device, an internal precharge command based on the precharge command; and
executing, by the memory device, the internal precharge command,
wherein the executing of the internal write command comprises executing the internal write command prior to executing the internal precharge command.

Example 18: The method of example 14 or any other example, further comprising:
receiving, by the memory device, a read command from the memory controller; and
executing the read command after executing the internal read command but prior to receiving the second command,
wherein the receiving of the read command occurs between the receiving of the first command and the receiving of the second command.

Example 19: The method of example 14 or any other example, further comprising:
receiving, by the memory device, a write command from the memory controller; and
executing the write command after executing the internal read command but prior to receiving the second command,
wherein the receiving of the write command occurs between the receiving of the first command and the receiving of the second command.

Example 20: The method of example 14 or any other example, wherein the executing of the internal read command comprises reading, by the memory device and based on the internal read command, data associated with usage-based disturbance prior to receiving the second command.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of implementing control circuitry that schedules aspects of usage-based disturbance mitigation based on different external commands have been described in language specific to certain features and/or methods, the subject of the appended claims is not necessarily limited to the specific features or methods described. Rather, the specific features and methods are disclosed as a variety of example implementations of scheduling aspects of usage-based disturbance mitigation based on different external commands.

What is claimed is:

1. An apparatus comprising:
a memory device comprising:
at least one bank comprising memory cells, wherein a subset of the memory cells is configured to store data associated with usage-based disturbance; and
circuitry configured to mitigate usage-based disturbance within the bank based on the data,
the memory device configured to:
receive, from a memory controller, two commands that are separated in time by a timing offset;
generate an internal read command based on a first command of the two commands to cause the memory device to read the data from the subset of the memory cells; and
generate an internal write command based on a second command of the two commands to cause the memory device to write modified data generated by the circuitry to the subset of the memory cells.

2. The apparatus of claim 1, wherein the first command received from the memory controller is an activate command.

3. The apparatus of claim 1, wherein the second command received from the memory controller is a precharge command.

4. The apparatus of claim 1, wherein the memory device is configured to read the data from the subset of the memory cells based on the internal read command prior to receiving the second command.

5. The apparatus of claim 4, wherein a timing offset between the first command and the second command at least includes a row address strobe (RAS) delay and a column address strobe (CAS) delay (tRCD).

6. The apparatus of claim 1, wherein the memory device is configured to write the modified data to the subset of the memory cells prior to receiving a subsequent command.

7. The apparatus of claim 6, wherein a timing offset between the second command and a subsequent command corresponds to a precharge time (tRP).

8. The apparatus of claim 1, wherein the subset represents a subset of the memory cells within each row of the bank.

9. An apparatus comprising:
a memory device comprising a plurality of memory cells arranged in rows, a subset of the memory cells configured to store data associated with usage-based disturbance in the rows,
the memory device configured to:
receive, from a memory controller, an activate command; and
read the data from the subset of the memory cells based on the activate command.

10. The apparatus of claim 9, wherein the memory device is configured to:
receive, from the memory controller, a precharge command that is separated in time from the activate command; and
write modified data generated based on the data to the subset of the memory cells based on the precharge command.

11. The apparatus of claim 10, wherein the memory device is configured to read the data from the subset of the memory cells prior to receiving the precharge command.

12. The apparatus of claim 10, wherein the memory device is configured to write the modified data to the subset of the memory cells prior to receiving a subsequent command.

13. The apparatus of claim 9, wherein:
each row includes the subset of the memory cells configured to store the data associated with usage-based disturbance;
the activate command is associated with a particular row; and
the memory device is configured to read the data from the row associated with the activate command.

14. A method comprising:
receiving, by a memory device, a first command from a memory controller;
executing, by the memory device, an internal read command associated with usage-based disturbance mitigation based on the first command;
receiving, by the memory device, a second command from the memory controller; and
executing, by the memory device, an internal write command associated with usage-based disturbance mitigation based on the second command.

15. The method of claim 14, wherein the receiving of the first command comprises receiving an activate command from the memory controller.

16. The method of claim 14, wherein the receiving of the second command comprises receiving a precharge command from the memory controller.

17. The method of claim 16, further comprising:
generating, by the memory device, an internal precharge command based on the precharge command; and
executing, by the memory device, the internal precharge command,
wherein the executing of the internal write command comprises executing the internal write command prior to executing the internal precharge command.

18. The method of claim 14, further comprising:
receiving, by the memory device, a read command from the memory controller; and
executing the read command after executing the internal read command but prior to receiving the second command,
wherein the receiving of the read command occurs between the receiving of the first command and the receiving of the second command.

19. The method of claim 14, further comprising:
receiving, by the memory device, a write command from the memory controller; and
executing the write command after executing the internal read command but prior to receiving the second command,
wherein the receiving of the write command occurs between the receiving of the first command and the receiving of the second command.

20. The method of claim 14, wherein the executing of the internal read command comprises reading, by the memory device and based on the internal read command, data associated with usage-based disturbance prior to receiving the second command.
